(19) United States
(12) Patent Application Publication
(10) Pub. No.: US 2015/0270372 A1
(43) Pub. Date: Sep. 24, 2015

(54) Method Of Forming Extended Source-Drain MOS Transistors

(71) Applicant: Silicon Storage Technology, Inc., San Jose, CA (US)

(72) Inventors: CHIEN-SHENG SU, Saratoga, CA (US); MANDANA TADAYONI, Cupertino, CA (US); YUEH-HSIN CHEN, Pleasanton, CA (US)

(21) Appl. No.: 14/733,904

(22) Filed: Jun. 8, 2015

Related U.S. Application Data
(62) Division of application No. 13/974,936, filed on Aug. 23, 2013.

(51) Int. Cl. H01L 29/66; H01L 21/265

(52) U.S. Cl. CPC H01L 29/66492; H01L 29/6653; H01L 21/265

(57) ABSTRACT

A transistor and method of making same include a substrate, a conductive gate over the substrate and a channel region in the substrate under the conductive gate. First and second insulating spacers are laterally adjacent to first and second sides of the conductive gate. A source region in the substrate is adjacent to but laterally spaced from the first side of the conductive gate and the first spacer, and a drain region in the substrate is adjacent to but laterally spaced apart from the second side of the conductive gate and the second spacer. First and second LD regions are in the substrate and laterally extend between the channel region and the source or drain regions respectively, each with a portion thereof not disposed under the first and second spacers nor under the conductive gate, and each with a dopant concentration less than that of the source or drain regions.

### RELATED APPLICATIONS

This application is a divisional application of U.S. patent application Ser. No. 13/974,936, filed Aug. 23, 2013, which claims the benefit of U.S. Provisional Application No. 61/706,587, filed Sep. 27, 2012, and which is incorporated herein by reference.

### FIELD OF THE INVENTION

The present invention relates to MOS transistors for high power devices.

### BACKGROUND OF THE INVENTION

FIG. 1 illustrates a conventional MOS transistor 2. The MOS transistor 2 includes a conductive gate 4 disposed over and insulated from a substrate 6 by a layer of insulation material 8. Source region 10 and drain region 12 are formed in the substrate, having a conductivity type opposite that of the substrate (or that of a well in the substrate). For example, for a P-type substrate or for a P-type well in an N-type substrate, source and drain regions have an N-type conductivity. Insulation spacers 14 are formed on lateral sides of the gate 4. The source 10 and drain 12 define a channel region 16 therebetween. The channel side edges of the source 10 and drain 12 are aligned with the edges of gate 4.

As illustrated in FIG. 2, it is also known to form source and drain regions using multiple doping steps. In particular, after formation of the gate 4, but before the formation of the spacers 14, a first implant is performed to form LD (lightly doped) regions 18 (which are self-aligned to the gate 4). After formation of the spacers 14, a second implant is performed to form source and drain regions 10/12 (which are self-aligned to the spacers 14). The LD regions 18 are disposed underneath the spacers 14, and they connect the source and drain regions 10/12 to the channel region 16.

For high-voltage applications, the implant energy and dose for forming LD regions 18 in a MOS transistor may not be the same as those for low-voltage logic MOS transistors formed on the same wafer. The implant energy should be relatively high to achieve sufficient high gated-drain junction breakdown voltage. Usually, the implant not only goes into the substrate for forming the transistor LD region 18, but it also goes into the transistor's gate poly 4. As semiconductor technologies migrate to a 65 nm geometry, a 45 nm geometry and beyond, the logic MOS gate poly thickness becomes thinner. A typical logic poly gate thickness is about 1000 Å for a 65 nm geometry, and 800 Å for a 45 nm geometry. Since high-voltage MOS transistors share the same poly as the low-voltage logic MOS transistors, the implant energy has to be reduced to prevent the penetration of the implant dopants, such as boron, phosphorus, or arsenic, into the MOS channel 16 under the gate poly 4. However, reducing the implant energy will result in a lower gated-drain junction breakdown voltage, and a high-voltage MOS transistor may fail to deliver a sufficiently high gated-drain junction breakdown voltage.

It is known to use extended drain MOS transistors to increase the gated drain junction breakdown voltage. FIG. 3 illustrates an extended drain NMOS transistor (i.e. formed in a P substrate 6), where the drain region 12 is formed away from the gate 4 and the spacer 14 (i.e. the drain region 12 is not self-aligned to the spacer 14, but instead is disposed laterally away from the gate 4 and the spacer 14). In the P-substrate 6, the source and drain regions 10/12 can be formed as N-type regions. FIG. 4 illustrates an extended PMOS transistor, which is formed in an N-well 20 of a P type substrate 6, where source/drain regions 10/12 and LD regions 18a/18b are P type.

The extended drain MOS transistor is not a symmetric device because the source is not extended. This means that the source 10 is aligned with (i.e. reaches) the spacer 14, and is connected to the channel region 16 by LD region 18a which itself is disposed underneath the spacer 14. In contrast, the drain 12 is positioned away from the spacer 14, and is connected to the channel region 16 by LD region 18b which is only partially disposed underneath spacer 14. When source and drain 10/12 of a MOS transistor is swapped by layout error, the device becomes an extended source MOS transistor. As a result, a high gated drain breakdown voltage may not be achieved.

In the current industry practice when the extended source and drain MOS transistor is used as a symmetric device, the poly gate material and part of source and drain are blocked from source/drain N+ or P+ implant. A special masking step is often needed to conduct implant doping of the gate material (polysilicon). Without doping, the gate poly material will have a depletion effect and the transistor threshold voltage will be shifted. In-situ doped poly material can replace implanted poly, but that solution would only work for one MOS (such as NMOS) but not for the other MOS (such as PMOS) unless a low-performance buried channel transistor is used.

There is a need for a MOS device, and method of making the same, that addresses the above identified issues.

### BRIEF SUMMARY OF THE INVENTION

The aforementioned problems and needs are addressed by a transistor having a substrate, a conductive gate disposed over and insulated from the substrate wherein a channel region in the substrate is disposed under the conductive gate, a first spacer of insulating material over the substrate and laterally adjacent to a first side of the conductive gate, a second spacer of insulating material over the substrate and laterally adjacent to a second side of the conductive gate that is opposite to the first side, a source region formed in the substrate and adjacent to but laterally spaced apart from the first side of the conductive gate and the first spacer, a drain region formed in the substrate and adjacent to but laterally spaced apart from the second side of the conductive gate and the second spacer, a first LD region formed in the substrate and laterally extending between the channel region and the source region wherein the first LD region has a first portion disposed under the first spacer and a second portion that is not disposed under the first and second spacers and not disposed under the conductive gate and wherein a dopant concentration of the first LD region is less than that of the source region, and a second LD region formed in the substrate and laterally extending between the channel region and the drain region wherein the second LD region has a first portion disposed under the second spacer and a second portion that is not disposed under the first and second spacers and not disposed under the conductive gate and wherein a dopant concentration of the second LD region is less than that of the drain region.

A method of forming a transistor, includes forming a conductive gate over and insulated from a substrate wherein a channel region in the substrate is disposed under the conductive gate, performing a first implant of dopant into portions of the substrate adjacent to opposing first and second sides of the conductive gate to form first and second LD regions respectively in the substrate, forming a first spacer of insulating material over the first LD region in the substrate and laterally adjacent to the first side of the conductive gate, forming a second spacer of insulating material over the second LD region in the substrate and laterally adjacent to the second side of the conductive gate, forming masking material that extends at least over portions of the substrate directly laterally adjacent to the first and second spacers but leaves exposed at least portions of the substrate laterally spaced apart from the first and second spacers, performing a second implant of dopant into the exposed portions of the substrate to form a source region in the substrate which is adjacent to but laterally spaced apart from the first side of the conductive gate and the first spacer and to form a drain region in the substrate which is adjacent to but laterally spaced apart from the second side of the conductive gate and the second spacer, wherein the first LD region laterally extends between the channel region and the source region and has a first portion disposed under the first spacer and a second portion that is not disposed under the first and second spacers and not disposed under the conductive gate and wherein a dopant concentration of the first LD region is less than that of the source region, and wherein the second LD region laterally extending between the channel region and the drain region and has a first portion disposed under the second spacer and a second portion that is not disposed under the first and second spacers and not disposed under the conductive gate and wherein a dopant concentration of the second LD region is less than that of the drain region.

Other objects and features of the present invention will become apparent by a review of the specification, claims and appended figures.

### BRIEF DESCRIPTION OF THE DRAWINGS

FIG. 1 is a side cross sectional view of a conventional MOS transistor.

FIG. 2 is a side cross sectional view of a conventional MOS transistor with lightly doped regions connecting the source and drain to the channel region.

FIG. 3 is a side cross sectional view of a conventional extended drain MOS transistor.

FIG. 4 is a side cross sectional view of a conventional extended drain PMOS transistor.

FIG. 5 is a side cross sectional view of a symmetric extended source/drain MOS transistor.

FIG. 6A-6D are side cross sectional views illustrating the formation of the symmetric extended source/drain NMOS transistor.

FIG. 7 is a side cross sectional view of a symmetric extended source/drain PMOS transistor.

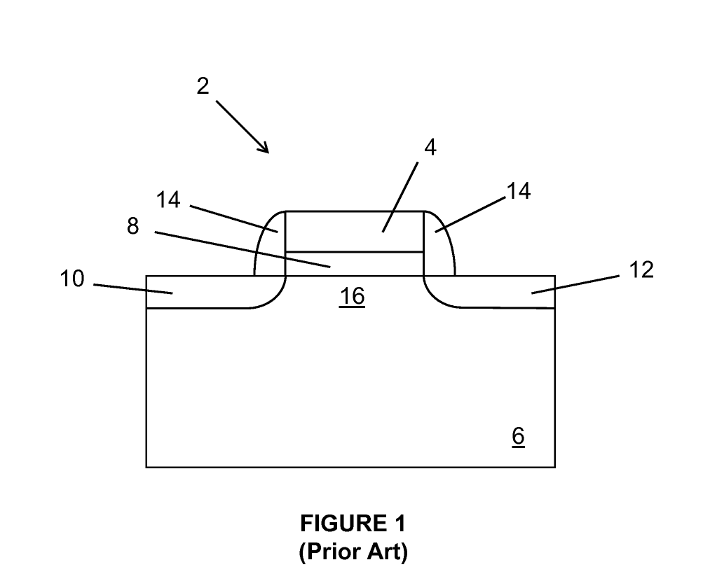

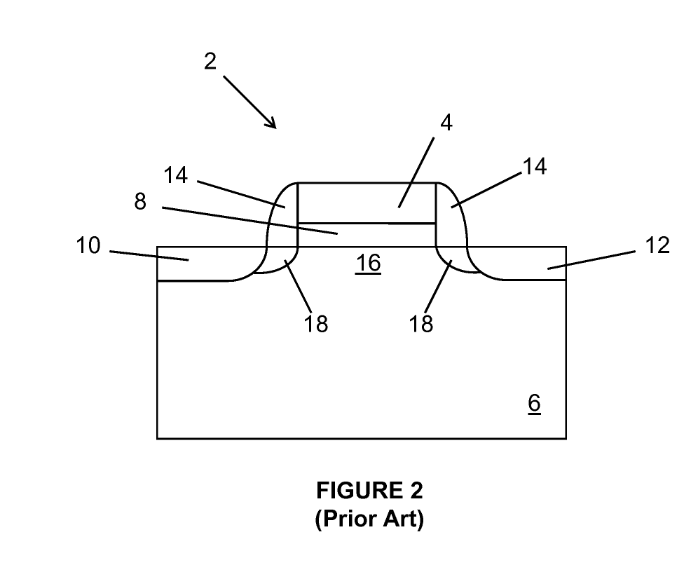

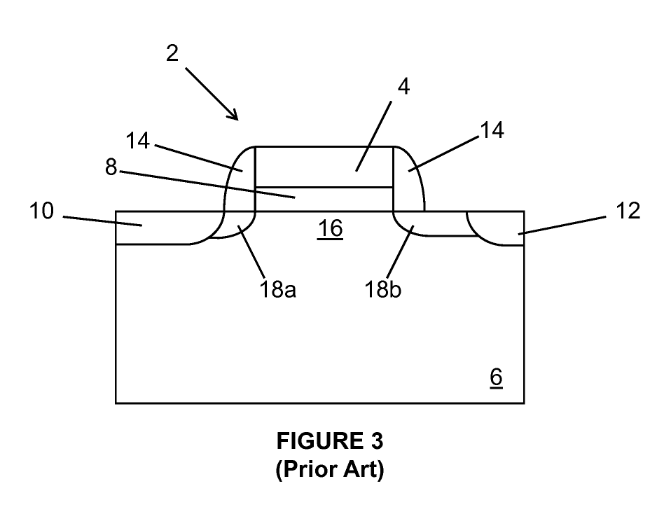

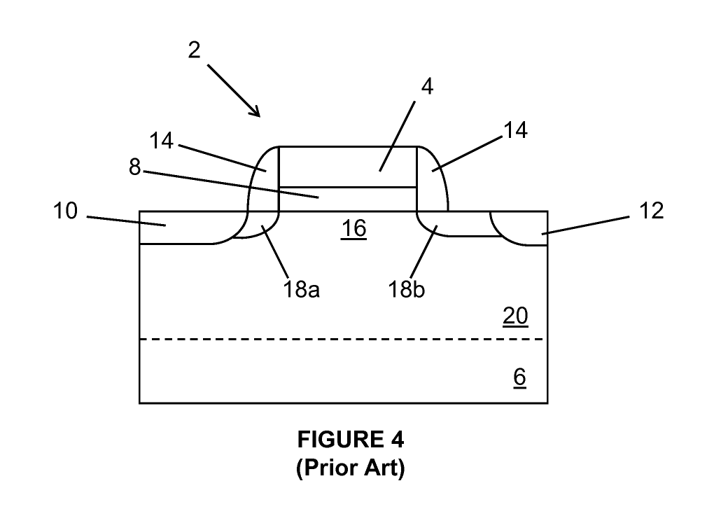

### DETAILED DESCRIPTION OF THE INVENTION

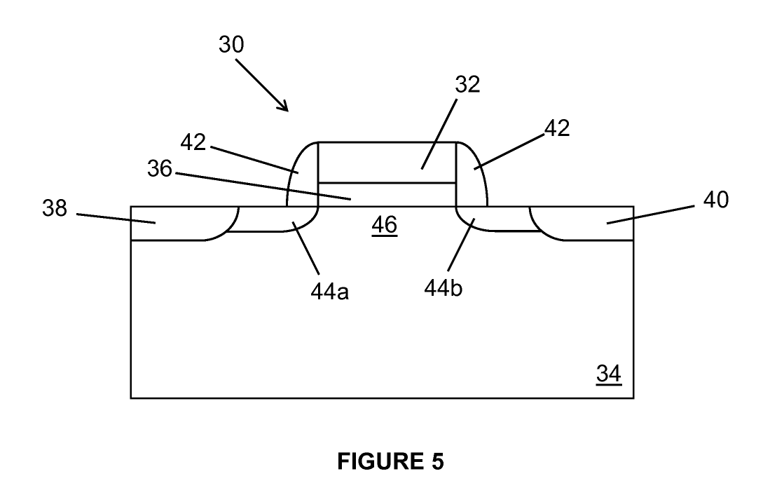

The present invention is a symmetric extended source/drain MOS transistor, as illustrated in FIG. 5, where both the source and the drain are extended away from the gate and the spacer. The extended source/drain MOS transistor 30 includes a conductive gate 32 disposed over and insulated from a substrate 34 by a layer of insulation material 36. Source region 38 and drain region 40 are formed in the substrate 34, having a conductivity type opposite that of the substrate (or that of a well in the substrate). For example, for a P-type substrate or P-type well in an N-type substrate, source and drain regions 38/40 have an N-type conductivity. Insulation spacers 42 are formed on lateral sides of the gate 32. Channel region 46 in the substrate 34 is underneath the gate 32. LD region 44a in the substrate 34 extends from channel region 46, underneath spacer 42, and beyond spacer 42 to source region 38. LD region 44b in the substrate 34 extends from channel region 46, underneath spacer 42, and beyond spacer 42 to drain region 40. Each LD regions 44a and 44b have a portion thereof not disposed underneath spacers 42. LD region 44a connects channel region 46 to source 38, which is spaced away from spacer 42. LD region 44b connects channel region 46 to drain 40, which is also spaced away from spacer 42. Gate 32 controls the conductivity of channel region 46 (i.e. a relative positive voltage on gate 32 makes channel region 46 conductive, otherwise channel region 46 is not conductive).

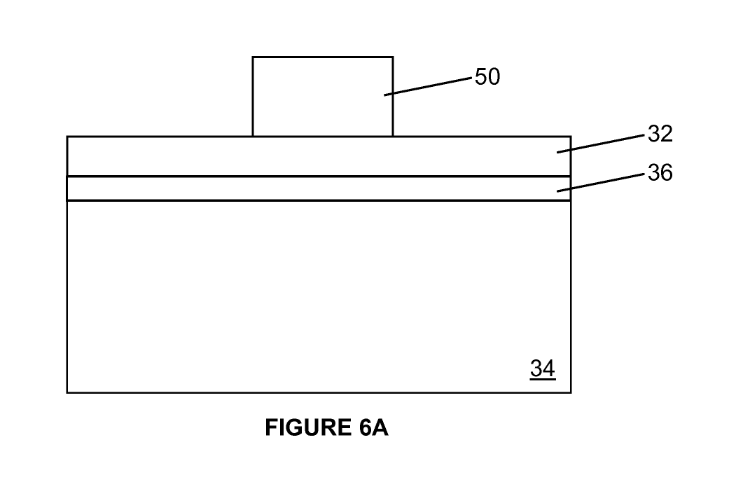

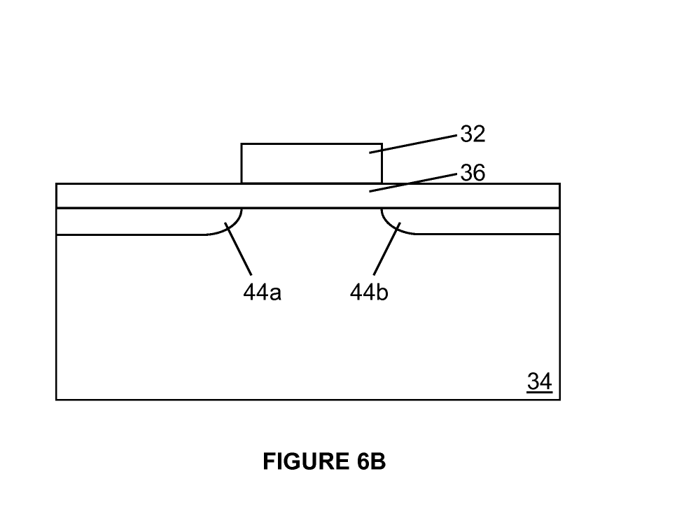

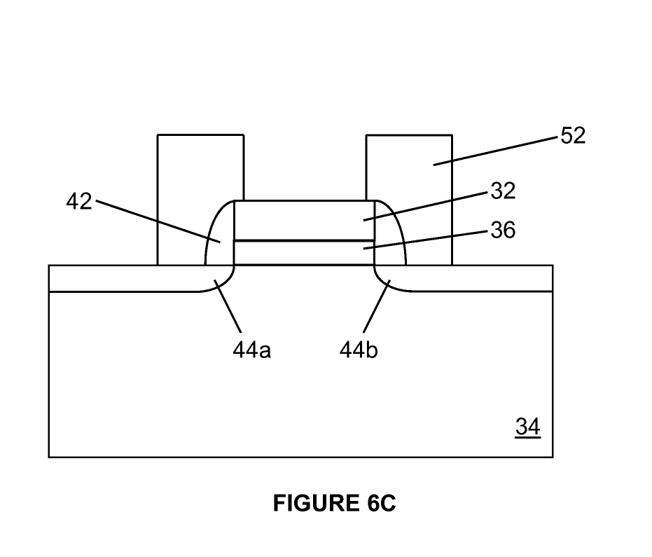

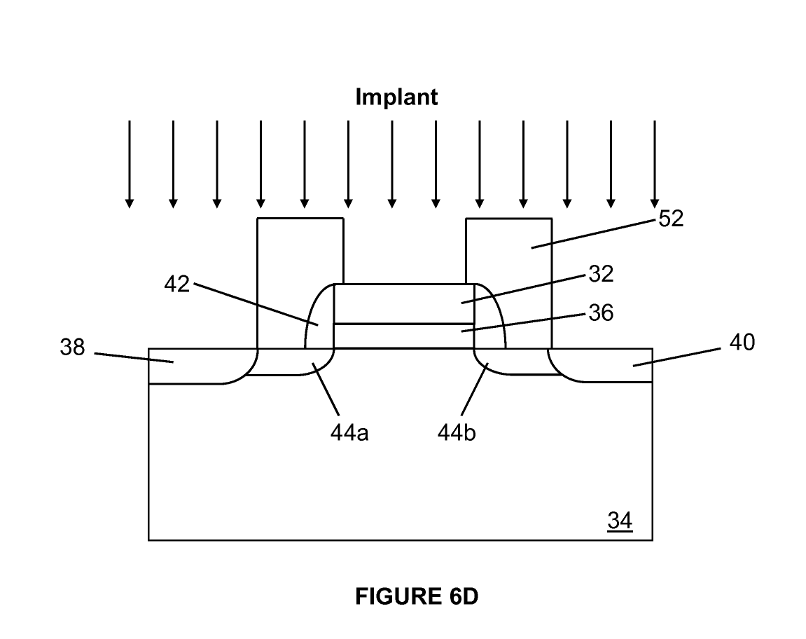

FIGS. 6A-6D illustrate the sequence of steps in forming the symmetric extended source/drain MOS transistor 30. The process begins with an insulation layer (e.g. silicon dioxide—oxide) 36 which is deposited or formed over the surface of the substrate 34. A conductive layer (e.g. polysilicon—poly) 32 is deposited over the oxide layer 36 (e.g. by depositing a non-conductive undoped polysilicon layer that later becomes conductive by subsequent implantation, such as by the source-drain implantation). A mask material 50 is deposited over the poly layer 52, followed by a photolithography process for selectively removing portions of the mask material exposing select portions of the poly layer 32. The resulting structure is shown in FIG. 6A.

An anisotropic poly etch is used to remove the exposed portions of poly layer 32, exposing portions of the oxide layer 36. The remaining portion of the poly layer 32 constitutes the gate. A first dopant implant process is used to form LD regions 44a and 44b in the portions of substrate 34 adjacent to gate 32. FIG. 6B shows the resultant structure after the mask material 50 has been removed.

Spacers of insulation material 42 are formed adjacent the gate 32. Formation of spacers is well known in the art, and involves the deposition of an insulating material or multiple materials over the contour of a structure, followed by an anisotropic etch process, whereby the material is removed from horizontal surfaces of the structure, while the material remains largely intact on vertically oriented surfaces of the 30 structure (with a rounded upper surface). Preferably, spacers 42 are formed of oxide and nitride, where a layer of oxide and another layer of nitride are deposited over the structure, followed by an anisotropic etch that removes the nitride and oxide except for those portions abutting the vertical sides of the gate 32. A masking photo resist 52 is coated over the structure, followed by a photolithography process for selectively removing portions of the photo resist 52 exposing the gate 32 and target locations of the substrate 34 that are spaced away from the gate 32 and away from the spacers 42. FIG. 6C shows the resultant structure.

A second implant process is used to implant dopant into the gate 32 as well as the exposed portions of the substrate 34 to form the source and drain regions 38/40 (which are separated away from the gate 32 and spacers 44), as illustrated in FIG. 6D. The photo resist 52 is then removed to result in the structure of FIG. 5.

With this design, an error-free layout can be achieved. It allows simultaneous doping to the poly gate 32 in the same implant step as the source/drain implant, thus eliminating an additional masking step. A thin poly layer can be used for the gate 32, and still achieve the desired doping in both the gate 32 and the substrate 34 (for source/drain regions 38/40). LD regions 44a/44b are more lightly doped than source drain regions 38/40 (i.e. dopant concentration per volume is less). By extending the more heavily doped source/drain junctions away from the gate edges, the junction profile under the gate 32 becomes gradual and less heavily doped, which results in 1) a reduction in the peak electric field, and 2) improved gate diode breakdown (by moving the high e-field away from the gate 32). Higher breakdown voltages can be achieved for both extended source/drain PMOS transistors and extended source/drain NMOS transistors.

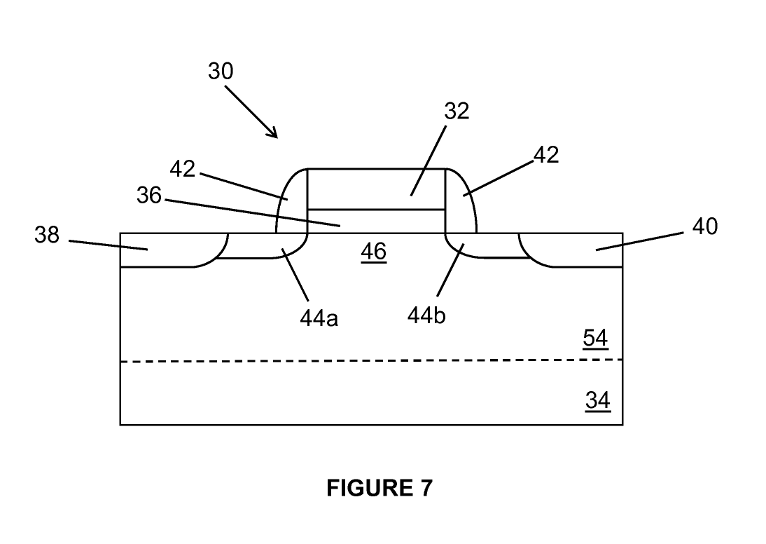

It is to be understood that the present invention is not limited to the embodiment(s) described above and illustrated herein, but encompasses any and all variations falling within the scope of the appended claims. For example, references to the present invention herein are not intended to limit the scope of any claim or claim term, but instead merely make reference to one or more features that may be covered by one or more of the claims. Materials, processes and numerical examples described above are exemplary only, and should not be deemed to limit the claims. Further, as is apparent from the claims and specification, not all method steps need be performed in the exact order illustrated or claimed, but rather in any order that allows the proper formation of the MOS transistor of the present invention. Single layers of material could be formed as multiple layers of such or similar materials, and vice versa. Lastly, FIG. 5 shows a symmetric extended source/drain NMOS transistor (formed with N+ dopants in a P type substrate), however, the present invention could be implemented as a symmetric extended source/drain PMOS transistor (formed with P+ dopants in an N-well 54 of a P type substrate 34) as illustrated in FIG. 7.

It should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between). For example, forming an element “over a substrate” can include forming the element directly on the substrate with no intermediate materials/elements therebetween, as well as forming the element indirectly on the substrate with one or more intermediate materials/elements therebetween.

What is claimed is:

1. A method of forming a transistor, comprising:
forming a conductive gate over and insulated from a substrate, wherein a channel region in the substrate is disposed under the conductive gate;
performing a first implant of dopant into portions of the substrate adjacent to opposing first and second sides of the conductive gate to form first and second lightly doped (LD) regions respectively in the substrate;
forming a first spacer of insulating material over the first LD region in the substrate and laterally adjacent to the first side of the conductive gate;
forming a second spacer of insulating material over the second LD region in the substrate and laterally adjacent to the second side of the conductive gate;
forming masking material that extends at least over portions of the substrate directly laterally adjacent to the first and second spacers but leaves exposed at least portions of the substrate laterally spaced apart from the first and second spacers;
performing a second implant of dopant into the exposed portions of the substrate to form a source region in the substrate which is adjacent to but laterally spaced apart from the first side of the conductive gate and the first spacer and to form a drain region in the substrate which is adjacent to but laterally spaced apart from the second side of the conductive gate and the second spacer;
wherein the first LD region laterally extends between the channel region and the source region and has a first portion disposed under the first spacer and a second portion that is not disposed under the first and second spacers and not disposed under the conductive gate, and wherein a dopant concentration of the first LD region is less than that of the source region; and
wherein the second LD region laterally extending between the channel region and the drain region and has a first portion disposed under the second spacer and a second portion that is not disposed under the first and second spacers and not disposed under the conductive gate, and wherein a dopant concentration of the second LD region is less than that of the drain region.

2. The method of claim 1, wherein:
the forming of the mask material further includes leaving exposed at least a portion of the conductive gate; and
the performing of the second implant further includes simultaneously implanting the dopant into the conductive gate and the exposed portions of the substrate.

3. The method of claim 1, wherein the masking material further extends over the first and second spacers.
